(19) United States
(12) Patent Application Publication
(10) Pub. No.: US 2003/0009866 A1
(43) Pub. Date: Jan. 16, 2003

(54) Capacitor manufacturing method

(75) Inventor: Keiichiro Kashihara, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 10/109,823

(22) Filed: Apr. 1, 2002

(30) Foreign Application Priority Data
Jul. 10, 2001 (JP) 2001-209139

(51) Int. Cl. H01G 7/00; H05K 3/20

(52) U.S. Cl. 29/25.42; 29/831; 29/25.41

(57) ABSTRACT

A capacitor manufacturing method is provided in which an underlying noble metal layer is not sputtered during formation of a hole in which a lower electrode is buried, and in which a dummy interlayer film is less apt to peel off. A stopper layer (9) is formed on an underlying noble metal layer (4) and a dummy interlayer film (5) is formed on the stopper layer (9). Therefore the underlying noble metal layer (4) is not sputtered by overetch during formation of holes (6a ) and (6b). Furthermore, the dummy interlayer film (5) is less apt to peel off since titanium used as the material of the stopper layer (9) has better adhesion to the dummy interlayer film formed of silicon oxide film than platinum used as the material of the underlying noble metal layer (4).

### BACKGROUND OF THE INVENTION

1. Field of the Invention

The present invention relates to a capacitor manufacturing method, and particularly to a method for manufacturing capacitors incorporated in DRAMs (Dynamic Random Access Memories).

2. Description of the Background Art

FIGS. 51 to 53 are sectional views showing a process for manufacturing capacitors according to a first conventional technique, particularly a process for manufacturing capacitors incorporated in a DRAM. While the capacitors incorporated in a DRAM are usually formed in an array, FIGS. 51 to 53 show a process for manufacturing one of the capacitors arranged in an array. In particular, FIGS. 51 to 53 show a process for forming a lower electrode in the capacitor manufacturing process.

As shown in FIG. 5 1, an interlayer insulating film 2 has a contact plug 3 in electrical contact with a substrate 1; a stopper layer 64 is formed on the interlayer insulating film 2 and a dummy interlayer film 5 is formed on the stopper layer 64. A hole 66, which reaches the contact plug 3, is formed through the dummy interlayer film 5 and the stopper layer 64. Next, as shown in FIG. 52, an electrically conductive material 67, the material of the lower electrode, e.g. platinum, is formed in the hole 66 and on top of the dummy interlayer film 5, e.g. by blanket CVD. Next, as shown in FIG. 53, the conductive material 67 is etched, e.g. by CMP, so that the conductive material 67 remains only in the hole 66; the lower electrode 68 of the capacitor is thus formed in the hole 66.

In the above-described first conventional capacitor manufacturing method, when the conductive material 67 is formed in the hole 66 by blanket CVD, the conductive material 67 is formed also on top of the dummy interlayer film 5. This requires use of a large amount of expensive CVD source, resulting in increased manufacturing cost. Furthermore, noble metals like platinum are usually difficult to remove by dry etching using chemical reactions (hereinafter referred to as chemical dry etching). It is therefore difficult to remove the conductive material 67 on the dummy interlayer film 5 in the process shown in FIG. 53 where the conductive material 67 is etched back by chemical dry etching.

To solve this problem, a second conventional technique is being suggested which selectively forms the lower electrode in a hole by utilizing catalytic action of the noble metal. FIGS. 54 to 63 are sectional views showing a capacitor manufacturing method of the second conventional technique, which, like FIGS. 51 to 53, show a process for manufacturing one of capacitors arranged in an array.

First, as shown in FIG. 54, an interlayer insulating film 2, e.g. a silicon oxide film, is formed on the substrate 1 and a contact plug 3 in electrical contact with the substrate 1 is formed in the interlayer insulating film 2. Then an underlying noble metal layer 4, e.g. of platinum, is formed on the interlayer insulating film 2 and the contact plug 3. Next, as shown in FIG. 55, a dummy interlayer film 5, e.g. a silicon oxide film, is formed on the underlying noble metal layer 4. Next, as shown in FIG. 56, a hole 76 is formed in the dummy interlayer film 5 by photolithography.

Next, as shown in FIG. 57, by taking advantage of the catalytic action of platinum, or the material of the underlying noble metal layer 4, a lower electrode 7 is selectively formed in the contact hole 76 by MOCVD (Metal Organic CVD). The lower electrode 7 is made of platinum, for example. Then, as shown in FIG. 58, the dummy interlayer film 5 is selectively removed, e.g. with dilute HF, and then the underlying noble metal layer 4 is selectively removed by dry etching as shown in FIG. 59, by using the lower electrode 7 as an etching mask. The underlying noble metal layer 4 and the lower electrode 7 obtained in the process step shown in FIG. 59 may be referred to as “lower electrode 8” together.

Next, as shown in FIG. 60, a dielectric film 10 is formed to cover the surface of the lower electrode 8 and the interlayer insulating film 2 and an upper electrode 11 is formed on the dielectric film 10; a capacitor incorporated in a DRAM is thus completed. The same contents as the capacitor manufacturing method shown in FIGS. 54 to 60 are described in Japanese Patent Application Laid-Open No. 8-97219 (1996), for example.

In the capacitor manufacturing method of the second conventional technique, the lower electrode 7 is selectively formed in the hole 76. Therefore the lower electrode 7 can be formed by using a less amount of CVD source than in the capacitor manufacturing method of the first conventional technique. Also, in the second conventional technique, while the underlying noble metal layer 4 is etched in the process shown in FIG. 59, the underlying noble metal layer 4 is usually thinner than the conductive material 67 formed on the dummy interlayer film 5 in the first conventional technique. It is therefore easier to etch the platinum in the second conventional technique than in the first conventional technique.

However, in the second conventional technique, the dry etching performed to form the hole 76 in the dummy interlayer film 5 involves not only chemical reactions but also physical reactions. This may cause the underlying noble metal layer 4 to be sputtered by overetch during formation of the hole 76 in the dummy interlayer film 5, and then platinum, the material of the underlying noble metal layer 4, will be redeposited on the side wall of the hole 76.

FIGS. 61 and 62 are sectional views showing platinum redeposited on the side wall of the hole 76 in the second conventional technique. In FIG. 61, only the top of the exposed part of the underlying noble metal layer 4 has been sputtered and the redeposits 14 have formed on the side wall of the hole 76. In FIG. 62, the exposed part of the underlying noble metal layer 4 has been entirely sputtered and the redeposits 14 have formed on the side wall of the hole 76. Since noble metals like platinum are generally susceptible to sputtering, the exposed part of the underlying noble metal layer 4 may be totally sputtered as shown in FIG. 62 depending on the overetch conditions.

It is usually difficult to selectively remove a noble metal like platinum redeposited on the side wall of the hole 76. When the underlying noble metal layer 4 has been sputtered and its material, platinum, has been attached on the side wall of the hole 76 as shown above, the diameter of the hole 76 changes. It is therefore difficult to obtain desired dimensions of the lower electrode 7 formed in the hole 76.

Furthermore, noble metals have poor adhesion to the silicon oxide film. Accordingly, in the process of FIG. 55, the dummy interlayer film 5 that is a silicon oxide film may peel off from the underlying noble metal layer 4 made of platinum, depending on the thickness of the dummy interlayer film 5. FIG. 63 is a sectional view showing the dummy interlayer film 5 peeling off in the second conventional technique.

### SUMMARY OF THE INVENTION

According to a first aspect of the present invention, a capacitor manufacturing method comprises the steps of: (a) forming an underlying noble metal layer; (b) forming a stopper layer to cover a surface of the underlying noble metal layer; (c) forming a dummy interlayer film to cover a surface of the stopper layer; (d) forming a first hole in the dummy interlayer film, the stopper layer being exposed in the first hole; (e) after the step (d), selectively removing the exposed part of the stopper layer to form a second hole in the stopper layer, the underlying noble metal layer being exposed in the second hole; and (f) selectively forming a lower electrode in the first and second holes by utilizing catalytic action of the material of the underlying noble metal layer.

Preferably, in the first aspect, the underlying noble metal layer is made of a platinum-group metal.

Preferably, in the first aspect, the platinum-group metal is platinum.

Preferably, in the first aspect, the capacitor manufacturing method further comprises, between the step (b) and the step (c), a step (g) of oxidizing the stopper layer.

Preferably, according to a second aspect, in the capacitor manufacturing method of the first aspect, the stopper layer is made of a material having better adhesion to the dummy interlayer film than the underlying noble metal layer.

Preferably, according to a third aspect, the capacitor manufacturing method of the first or second aspect further comprises a step (g) of, before the step (a), forming, in an interlayer insulating film, a contact plug having its top surface exposed in a surface of the interlayer insulating film, and in the step (a), the underlying noble metal layer is formed to cover the surface of the interlayer insulating film and the top surface of the contact plug.

Preferably, according to a fourth aspect, in the capacitor manufacturing method of the first or second aspect, the step (a) is achieved by forming, in an interlayer insulating film, a contact plug having the underlying noble metal layer at least in its upper end, the surface of the underlying noble metal layer being exposed in a surface of the interlayer insulating film, and in the step (b), the stopper layer is formed to also cover the surface of the interlayer insulating film.

Preferably, in the fourth aspect, the step (a) comprises the steps of: (g) forming the interlayer insulating film on a substrate, (h) after the step (g), forming a third hole in the interlayer insulating film, the substrate being exposed in the third hole, (i) after the step (h), forming a barrier metal layer on the exposed substrate, and (j) forming the underlying noble metal layer to cover a surface of the barrier metal layer.

Preferably, according to a fifth aspect, in the capacitor manufacturing method of the fourth aspect, the interlayer insulating film comprises a first interlayer insulating film and a second interlayer insulating film, and the contact plug comprises a first contact plug and a second contact plug which is the underlying noble metal layer, and wherein the step (a) comprises the steps of: (g) forming, in the first interlayer insulating film, the first contact plug having its top surface exposed in a surface of the first interlayer insulating film, (h) forming the second interlayer insulating film to cover the surface of the first interlayer insulating film and the top surface of the first contact plug, and (i) forming, in the second interlayer insulating film, the second contact plug having its bottom surface in contact with the top surface of the first contact plug and its top surface exposed in a surface of the second interlayer insulating film, and wherein in the step (b), the stopper layer is formed to cover the top surface of the second contact plug and the surface of the second interlayer insulating film.

According to the capacitor manufacturing method of the first aspect of the present invention, a stopper layer is formed on the underlying noble metal layer and a dummy interlayer film is formed on the stopper layer, where the underlying noble metal layer is formed of platinum and the dummy interlayer film is formed of silicon oxide film, for example. This structure prevents the underlying noble metal layer from being sputtered by overetch during formation of the first hole in the dummy interlayer film, thus preventing the material of the underlying noble metal layer, platinum, from being redeposited on the side wall of the first hole. When titanium is used as the stopper layer, the second hole is formed in the stopper layer by selectively removing the exposed part of the stopper layer by wet etching and therefore the underlying noble metal layer is not sputtered. This prevents redeposition of the material of the underlying noble metal layer, platinum, on the side wall of the second hole. The material of the underlying noble metal layer, which is generally difficult to remove, is thus not redeposited on the side walls of the first and second holes, and hence the diameters of the first and second holes are not changed. The lower electrode can thus be easily formed to desired dimensions.

According to the capacitor manufacturing method of the second aspect, the stopper layer is formed of a material having better adhesion to the dummy interlayer film than the underlying noble metal layer. Accordingly, as compared with a conventional technique in which the dummy interlayer film is formed directly on the surface of the underlying noble metal layer, the dummy interlayer film is less apt to peel off after it has been formed in the step (c).

According to the capacitor manufacturing method of the third aspect, the underlying noble metal layer is formed to cover the surface of the interlayer insulating film and the top surface of the contact plug. The lower electrode is therefore formed in a shorter time than in a structure in which the underlying noble metal layer is provided in the upper end of the contact plug. More specifically, when the underlying noble metal layer is provided in the upper end of the contact plug and a second hole having a larger opening area than the diameter of the contact plug is made, the exposed area of the underlying noble metal layer is smaller than the opening area of the second hole. In contrast, in the method of the third aspect, the exposed area of the underlying noble metal layer, which is exposed by formation of the second hole, is equal to the opening area of the second hole. Accordingly, when a second hole having a larger opening area than the diameter of the contact plug is formed, the exposed area of the underlying noble metal layer is larger in the method of the third aspect than in the method in which the underlying noble metal layer is formed in the upper end of the contact plug. Since the lower electrode is formed by taking advantage of catalytic action of the material of the underlying noble metal layer, the lower electrode can be formed in a shorter time as the exposed area of the underlying noble metal layer is larger. The method of the third aspect thus shortens the time for forming the lower electrode, as compared with the method in which the underlying noble metal layer is formed in the upper end of the contact plug.

According to the capacitor manufacturing method of the fourth aspect, each contact plug has the underlying noble metal layer formed at least in its upper end. Accordingly, the individual lower electrodes are already separated when they are formed in the first and second holes. Hence, capacitors of desired shape can be obtained more easily as compared with a method in which the lower electrodes are separated after they have been formed. More specifically, when the underlying noble metal layer is formed to cover the top surfaces of the contact plugs and the surface of the interlayer insulating film and a plurality of lower electrodes are formed, the lower electrodes formed in the first and second holes are connected to each other through the underlying noble metal layer. Therefore a process step is required after the step (f) to selectively remove the underlying noble metal layer to separate the lower electrodes. In this process step, the upper ends of the lower electrodes may be removed and the lower electrodes cannot be formed in desired shape, making it difficult to obtain capacitors of desired capacitance. However, in the method of the fourth aspect, the contact plugs have underlying noble metal layers formed in their respective upper ends and the stopper layer is formed to cover the surfaces of the underlying noble metal layers and the surface of the interlayer insulating film. The lower electrodes are therefore already separated when they are formed in the first and second holes. Thus this method does not require the process step of separating the lower electrodes after the step (f), solving the problem shown above. The time for forming the lower electrodes can thus be shorter than in a process in which the underlying noble metal layers are formed to cover the top surfaces of the contact plugs and the surface of the interlayer insulating film.

According to the capacitor manufacturing method of the fifth aspect, the first contact plug and the second contact plug, or the underlying noble metal layer, are formed in different interlayer insulating films. Accordingly a contact plug of desired shape can be obtained more easily than by a method in which a contact plug having the underlying noble metal layer is formed in a single layer of interlayer insulating film. More specifically, forming a contact plug having the underlying noble metal layer in its upper end in a single layer of interlayer insulating film usually requires a process (recessing process) of selectively removing the contact plug formed in the interlayer insulating film, so as to recess the top surface of the contact plug from the surface of the interlayer insulating film. In this process, depending on the materials of the contact plug and the interlayer insulating film, or depending on the etching conditions, a sufficient selectivity cannot be secured and the interlayer insulating film may be removed, making it difficult to obtain a contact plug of desired shape. In contrast, the first contact plug and the second contact plug are formed in separate interlayer insulating films in the method of the fifth aspect, which eliminates the need for the recessing process. The problem shown above has thus been solved and a contact plug of desired shape can be formed more easily than in a method in which a contact plug having the underlying noble metal layer is formed in a single layer of interlayer insulating film.

The present invention has been made to solve the problems shown above, and an object of the present invention is to provide a capacitor manufacturing method in which the underlying noble metal layer 4, made of a difficult-to-remove noble metal, is not sputtered during formation of a hole in which the lower electrode of the capacitor is buried, and in which the dummy interlayer film 5 made of silicon oxide film is less likely to peel off.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 12 are sectional views showing a capacitor manufacturing process according to a first preferred embodiment of the present invention;

FIGS. 13 to 32 are sectional views showing a capacitor manufacturing process according to a second preferred embodiment of the present invention;

FIG. 33 is a sectional view showing the capacitor manufacturing process of the first preferred embodiment of the present invention;

FIGS. 34 and 35 are sectional views showing the capacitor manufacturing process of the second preferred embodiment of the present invention;

FIGS. 36 to 49 are sectional views showing a capacitor manufacturing process according to a third preferred embodiment of the present invention;

FIG. 50 is a sectional view showing the capacitor manufacturing process of the first preferred embodiment of the present invention;

FIGS. 51 to 53 are sectional views showing a capacitor manufacturing process according to a first conventional technique;

FIGS. 54 to 60 are sectional views showing a capacitor manufacturing process according to a second conventional technique;

FIGS. 61 and 62 are sectional views showing redeposition of platinum on the side wall of the hole 76 in the second conventional technique; and

FIG. 63 is a sectional view showing the dummy interlayer film 5 peeling off in the second conventional technique.

### DESCRIPTION OF THE PREFERRED EMBODIMENTS

First Preferred Embodiment

FIGS. 1 to 12 are sectional views showing a capacitor manufacturing method according to a first preferred embodiment of the present invention; in particular, they show a process of manufacturing capacitors incorporated in a DRAM.

First, as shown in FIG. 1, an interlayer insulating film 2 is formed on a substrate I1 and contact plugs 3a and 3b in electrical contact with the substrate 1 are formed at a given interval in the interlayer insulating film 2. In this process, the top surface of the structure obtained in the process of FIG. 1 is planarized by CMP and the top surfaces 13a and 13b of the contact plugs 3a and 3b are exposed in the surface 12 of the interlayer insulating film 2. The top surfaces 13a and 13b of the contact plugs 3a and 3b and the surface 12 of the interlayer insulating film 2 are located in approximately the same plane. In other words, the process shown in FIG. 1 is a process of forming, in the interlayer insulating film 2, the contact plugs 3a and 3b having their top surfaces 13a and 13b exposed in the surface 12 of the interlayer insulating film 2.

The interlayer insulating film 2 is a silicon oxide film formed by CVD using TEOS (tetraethylorthosilicate), for example, and the contact plugs 3a and 3b are made of polysilicon, tungsten (W), or titanium nitride (TiN) formed by CVD, for example. The contact plugs 3a and 3b each have a diameter of 1000 to 1500 Å.

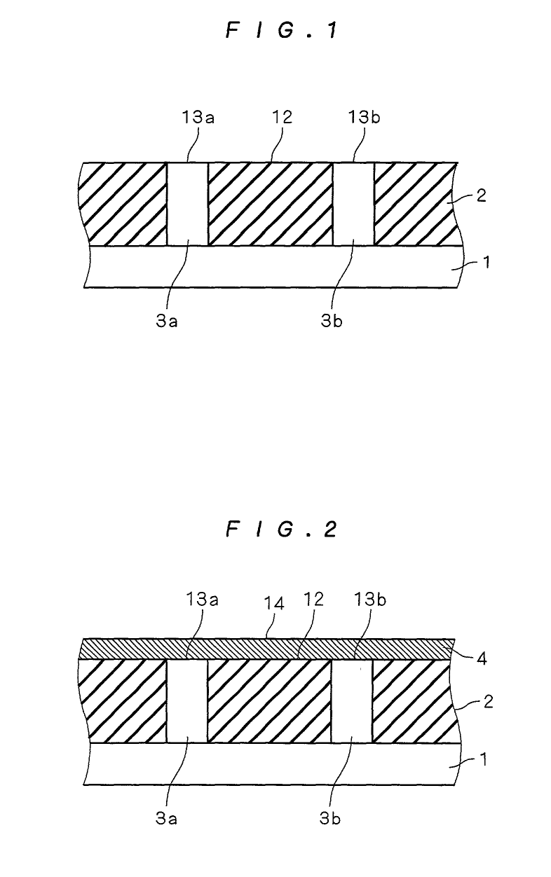

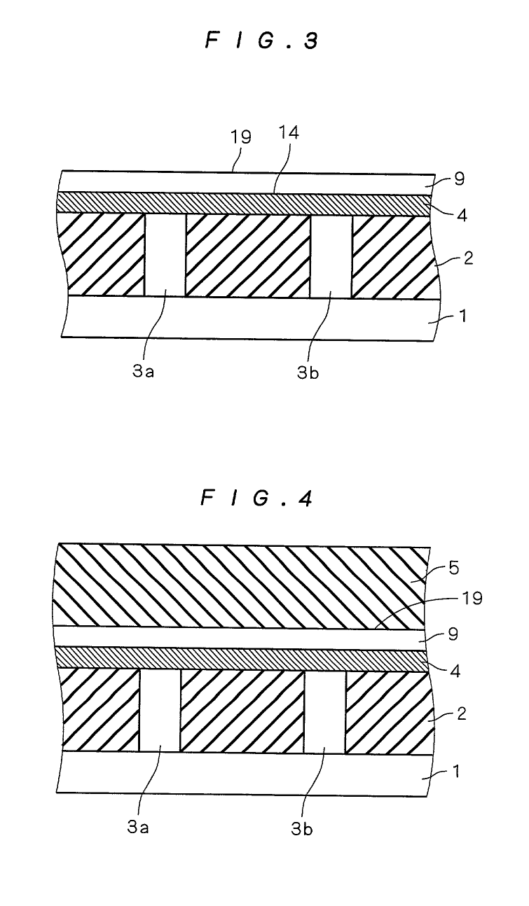

Next, as shown in FIG. 2, an underlying noble metal layer 4 is formed to 500 to 1000 Å by sputtering or CVD to cover the surface 12 of the interlayer insulating film 2 and the top surfaces 13a and 13b of the contact plugs 3a and 3b. Then, as shown in FIG. 3, a stopper layer 9 is formed to 50 to 200 Å by sputtering or CVD to cover the surface 14 of the underlying noble metal layer 4. A noble metal of the platinum group, i.e. platinum (Pt), ruthenium (Ru), iridium (Ir), palladium (Pd), rhodium (Rh), or osmium (Os), is used as the material of the underlying noble metal layer 4, for example. Titanium (Ti) or other material, such as TiN, TiSiN, or TiAlN, is used as the material of the stopper layer 9, for example.

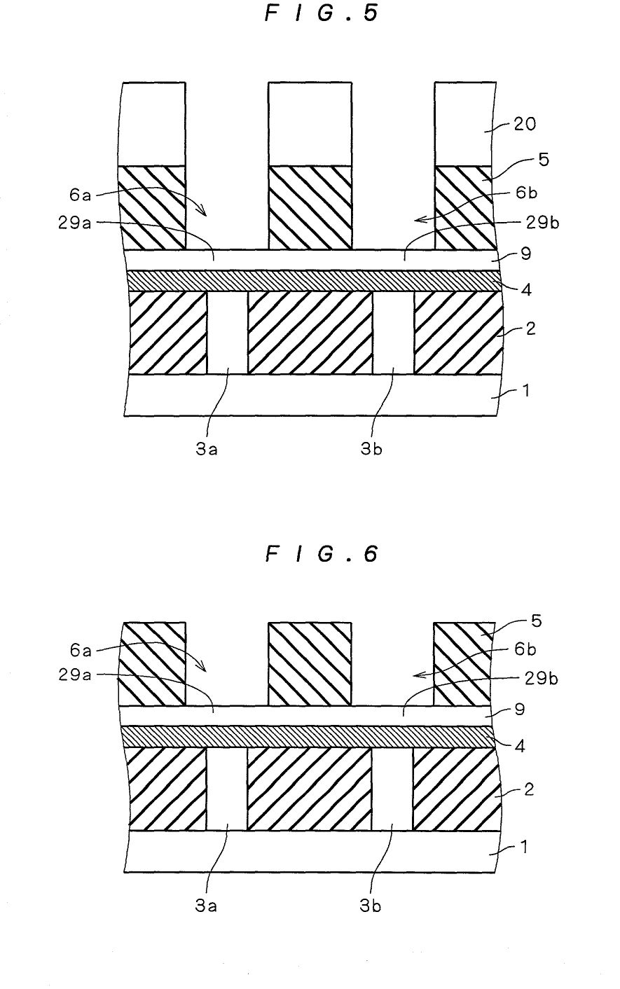

Next, as shown in FIG. 4, a dummy interlayer film 5 is formed to 4000 to 8000 Å to cover the surface 19 of the stopper layer 9. The dummy interlayer film 5 is a silicon oxide film formed by CVD with TEOS, in particular by plasma CVD. Next, as shown in FIG. 5, holes 6a and 6b are formed in the dummy interlayer film 5 by photolithography; the holes 6a and 6b are located above the contact plugs 3a and 3b. More specifically, a resist 20 is formed on the dummy interlayer film 5 and patterned. The dummy interlayer film 5 is then dry-etched by using the resist 20 as a mask to make the holes 6a and 6b in which the stopper layer 9 is exposed. Next, as shown in FIG. 6, the resist 20, used to form the holes 6a and 6b, is removed.

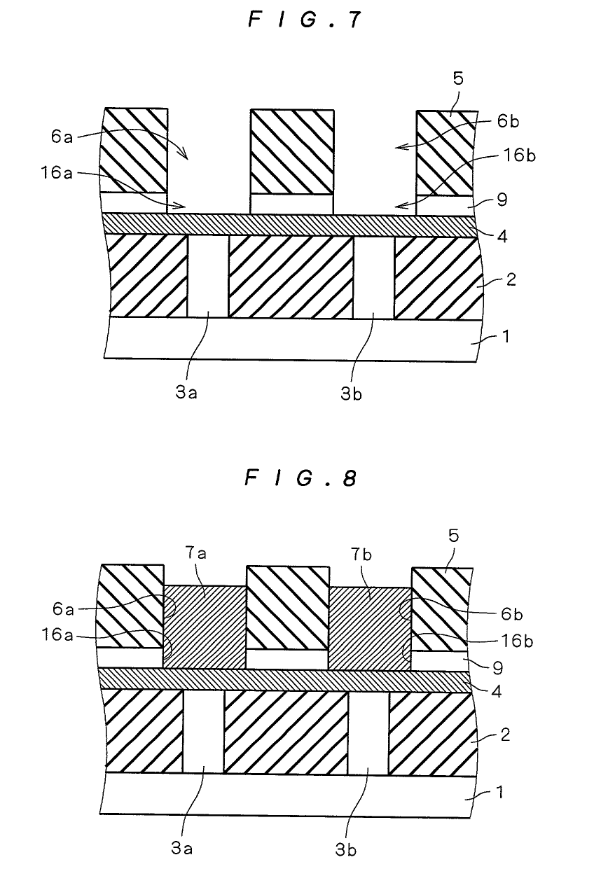

Next, as shown in FIG. 7, the exposed parts 29a and 29b of the stopper layer 9 are selectively removed by wet etching using a hydrogen peroxide solution or a mixture solution of sulfuric acid and hydrogen peroxide solution, so as to form holes 16a and 16b in the stopper layer 9; the underlying noble metal layer 4 is exposed in the holes 16a and 16b. When TiN or TiAlN is used as the material of the stopper layer 9, as in the case of Ti, the exposed parts 29a and 29b of the stopper layer 9 can be removed by using a hydrogen peroxide solution or a mixture solution of sulfuric acid and hydrogen peroxide solution. When TiSiN is used as the material of the stopper layer 9, the exposed parts 29a and 29b of the stopper layer 9 can be selectively removed by using a mixture solution of hydrofluoric acid and hydrogen peroxide solution.

Next, as shown in FIG. 8, by taking advantage of the catalytic action of the material of the underlying noble metal layer 4, i.e. a platinum-group metal, lower electrodes 7a and 7b are selectively formed in the holes 6a and 6b and the holes 16a and 16b. The lower electrodes 7a and 7b are made of a platinum-group metal, e.g. platinum, as well as the underlying noble metal layer 4.

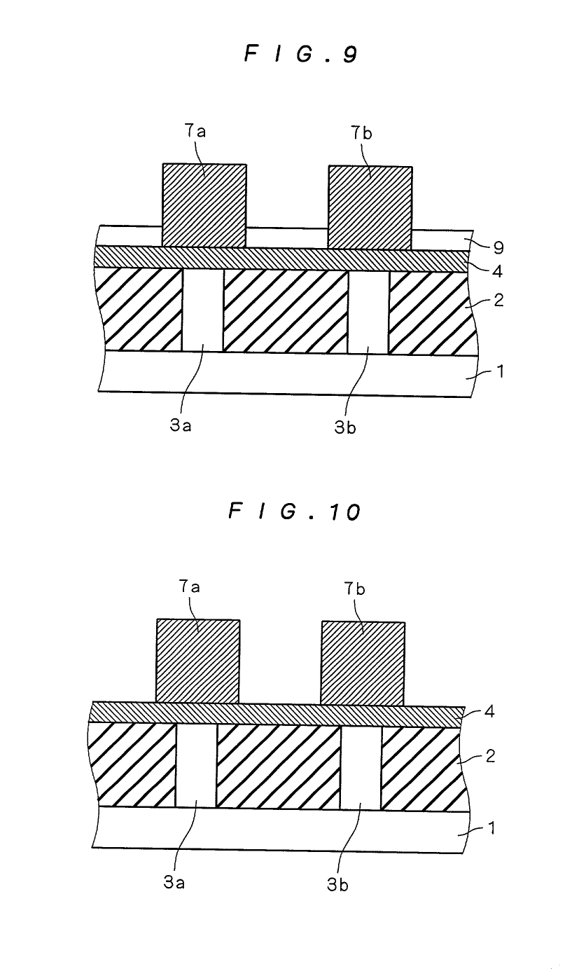

Next, as shown in FIG. 9, the dummy interlayer film 5 is selectively removed by using a dilute HF solution and the stopper layer 9 is selectively removed as shown in FIG. 10 by wet etching using a hydrogen peroxide solution or a mixture solution of sulfuric acid and hydrogen peroxide solution. As in the process shown in FIG. 7, when TiN or TiAlN is used as the material of the stopper layer 9, the stopper layer 9 can be selectively removed by using a hydrogen peroxide solution or a mixture solution of sulfuric acid and hydrogen peroxide solution, and when TiSiN is used as the material of the stopper layer 9, the stopper layer 9 can be selectively removed by using a mixture solution of hydrofluoric acid and hydrogen peroxide solution.

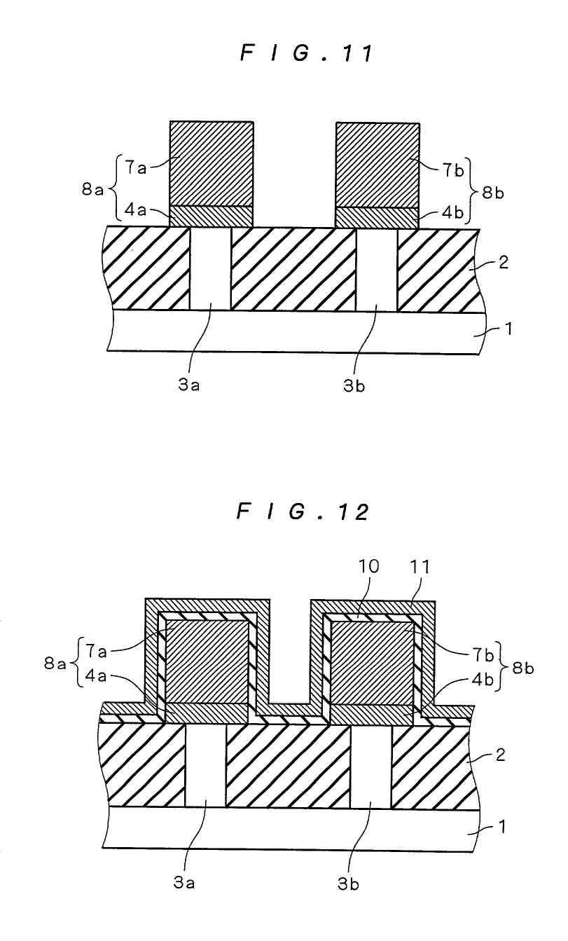

The lower electrodes 7a and 7b obtained in the process shown in FIG. 10 are connected to each other through the underlying noble metal layer 4. Hence, as shown in FIG. 11, the underlying noble metal layer 4 is selectively removed by sputter etching using a mixture gas of Ar and O₂ by using the lower electrodes 7a and 7b as etching masks, so as to separate the lower electrode 7a and the lower electrode 7b. The underlying noble metal layers 4a and 4b and the lower electrodes 7a and 7b obtained in the process shown in FIG. 11 may be referred to as “lower electrodes 8a and 8b” together.

Next, as shown in FIG. 12, a dielectric film 10 is formed to 200 to 300 Å to cover the surface of the lower electrodes 8a and 8b and the interlayer insulating film 2, and an upper electrode 11 is formed to 300 to 500 Å on the dielectric film 10; capacitors incorporated in a DRAM are thus completed. The capacitors formed through the processes shown in FIGS. 1 to 12 are called “damascene pillar capacitors.” According to the capacitor manufacturing method of the first preferred embodiment shown in FIGS. 1 to 12, the stopper layer 9 is formed on the underlying noble metal layer 4 and the dummy interlayer film 5 is formed on the stopper layer 9. Therefore, in the process shown in FIG. 5, the underlying noble metal layer 4 is not sputtered by overetch during formation of the holes 6a and 6b in the dummy interlayer film 5. The platinum-group metal forming the underlying noble metal layer 4 is therefore not redeposited on the side walls of the holes 6a and 6b. In the process shown in FIG. 5, the stopper layer 9 may be sputtered by the dry etching and the material of the stopper layer 9 may be redeposited on the side walls of the holes 6a and 6b. However, since the stopper layer 9 is made not of a noble metal but of a material like titanium, the redeposits on the side walls of the holes 6a and 6b can be selectively removed with a conventionally available solvent, such as 106 solution (a mixture solution of dimethyl sulfoxide and monoethanolamine), or EKC (registered trademark: a mixture solution of hydroxylamine, diglycolamine and catechol).

Furthermore, in the process shown in FIG. 7 where the holes 16a and 16b are made in the stopper layer 9, the underlying noble metal layer 4 is not sputtered since the exposed parts 29a and 29b of the stopper layer 9 are selectively removed by wet etching. The material of the underlying noble metal layer 4, i.e. platinum-group metal, is thus not redeposited on the side walls of the holes 16a and 16b.

As described above, in the capacitor manufacturing method of the first preferred embodiment, the material of the underlying noble metal layer 4 is not redeposited on the side walls of the holes 6a and 6b and the holes 16a and 16b. Accordingly the diameters of the holes 6a and 6b and 16a and 16b are not changed. This enables easy formation of the lower electrodes 7a and 7b of desired dimensions.

Moreover, since titanium used as the material of the stopper layer 9 has better adhesion to the dummy interlayer film 5, i.e. silicon oxide film, than platinum used as the material of the underlying noble metal layer 4. Accordingly the dummy interlayer film 5 is less apt to peel off in the process shown in FIG. 4. Also when TiN, TiSiN or TiAlN is used as the material of the stopper layer 9 as mentioned above, the dummy interlayer film 5 is less apt to peel off in the process of FIG. 4 for the same reason.

In the first preferred embodiment, an oxidation treatment may be applied to the stopper layer 9 after the process of FIG. 3, i.e. after the stopper layer 9 has been formed on the underlying noble metal layer 4. In this treatment, the stopper layer 9 is oxidized and titanium oxide (TiO) is produced. Titanium oxide is generally more difficult to remove by dry etching than titanium. This prevents, in the process of FIG. 5, the exposed parts 29a and 29b of the stopper layer 9 from being totally etched by overetch during formation of the holes 6a and 6b, thus preventing the underlying noble metal layer 4 from being undesirably sputtered. The same applies also when TiN, TiSiN, or TiAlN is used as the material of the stopper layer 9.

Second Preferred Embodiment

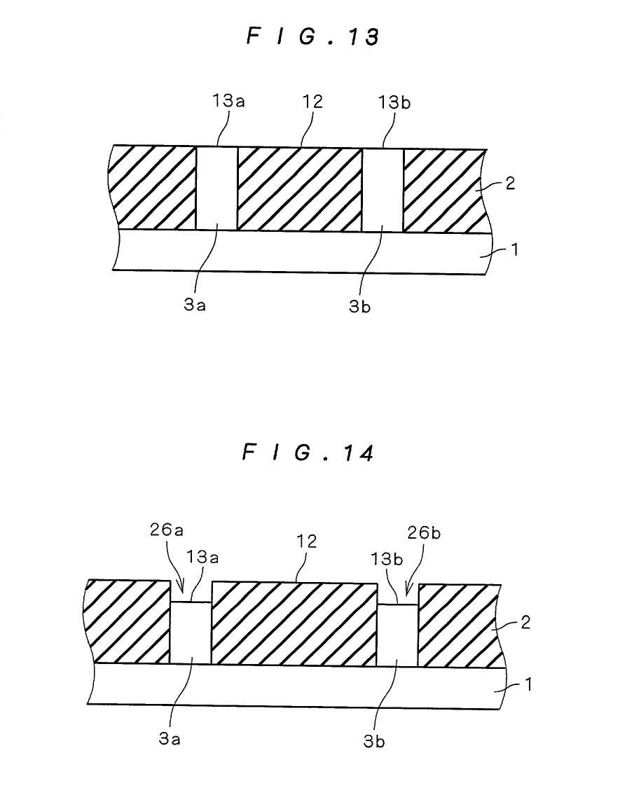

FIGS. 13 to 25 are sectional views showing a capacitor manufacturing process according to a second preferred embodiment of the present invention. In the first preferred embodiment, the underlying noble metal layer 4 is formed to cover the interlayer insulating film 2 and the contact plugs 3a and 3b. In contrast, in the second preferred embodiment, underlying noble metal layers 24a and 24b are formed in the upper ends of contact plugs 30a and 30b.

First, as shown in FIG. 13, the interlayer insulating film 2, e.g. a silicon oxide film, is formed on the substrate 1 and the contact plugs 3a and 3b in electrical contact with the substrate 1 are formed at a given interval in the interlayer insulating film 2. The top surface of the structure obtained in the process of FIG. 13 is planarized by CMP and the top surfaces 13a and 13b of the contact plugs 3a and 3b are exposed in the surface 12 of the interlayer insulating film 2. The top surfaces 13a and 13b of the contact plugs 3a and 3b and the surface 12 of the interlayer insulating film 2 are located in approximately the same plane. The contact plugs 3a and 3b each have a diameter of 1000 to 1500 Å.

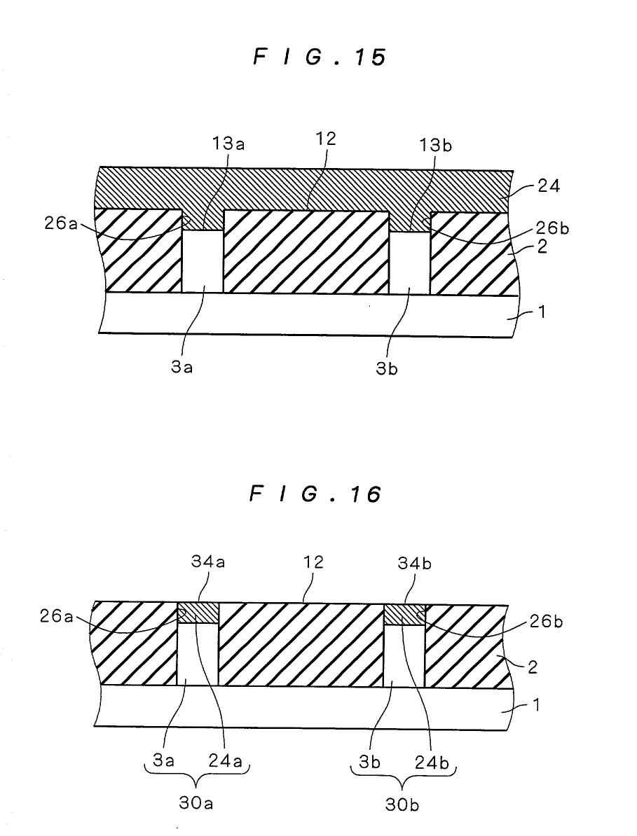

Next, as shown in FIG. 14, the upper ends of the contact plugs 3a and 3b are selectively removed by dry etching, so that the top surfaces 13a and 13b of the contact plugs 3a and 3b are recessed by 500 to 1000 Å from the surface 12 of the interlayer insulating film 2, so as to form holes 26a and 26b in the interlayer insulating film 2. Next, as shown in FIG. 15, an electrically conductive material 24 is formed by sputtering in the holes 26a and 26b and on the surface 12 of the interlayer insulating film 2. The process shown in FIG. 14 in which the contact plugs 3a and 3b are selectively etched to recess the top surfaces 13a and 13b of the contact plugs 3a and 3b from the surface 12 of the interlayer insulating film 2 may be referred to as “recessing process.”

Next, as shown in FIG. 16, the conductive material 24 is removed by sputter etching using a mixture gas of Ar and O₂, so that the conductive material 24 remains only in the holes 26a and 26b, thus forming the underlying noble metal layers 24a and 24b in the holes 26a and 26b. At this time the surfaces 34a and 34b of the underlying noble metal layers 24a and 24b are exposed in the surface 12 of the interlayer insulating film 2. The conductive material 24, or the underlying noble metal layers 24a and 24b, are made of a platinum-group metal. The underlying noble metal layers 24a and 24b are formed in the interlayer insulating film 2 together with the contact plugs 3a and 3b and used with the contact plugs 3a and 3b to make connection between the substrate 1 and lower electrodes 7a and 7b described later. Therefore the underlying noble metal layers 24a and 24b and the contact plugs 3a and 3b may be referred to as “contact plugs 30a and 30b” together. While the underlying noble metal layers 24a and 24b are formed respectively on the contact plugs 3a and 3b in the process of FIG. 16, it can be said in other words that the contact plugs 30a and 30b have the underlying noble metal layers 24a and 24b formed in their respective upper ends.

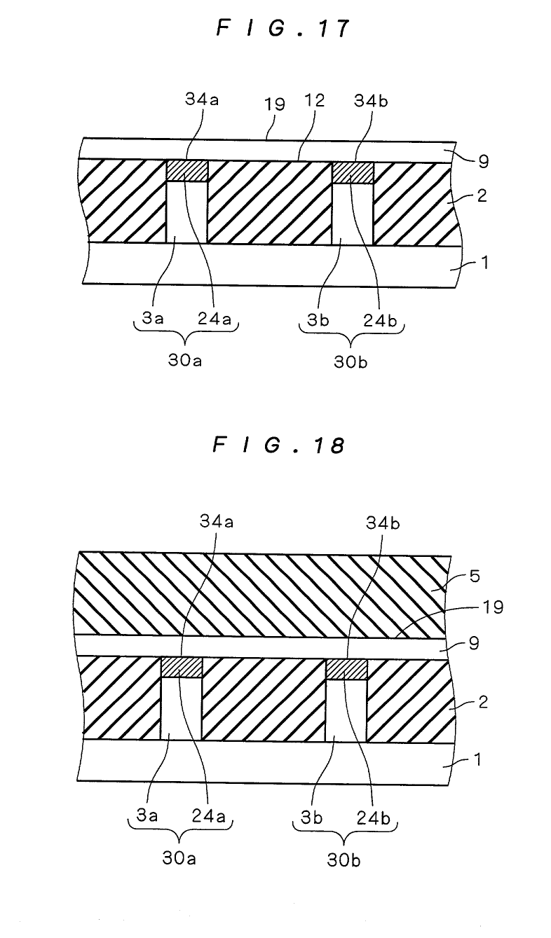

Next, as shown in FIG. 17, the stopper layer 9 is formed to 500 to 1000 Å to cover the surface 12 of the interlayer insulating film 2 and the surfaces 34a and 34b of the underlying noble metal layers 24a and 24b. Ti, TiN, TiSiN, or TiAlN is used as the material of the stopper layer 9, for example. Then, as shown in FIG. 18, the dummy interlayer film 5, e.g. a silicon oxide film, is formed to 4000 to 8000 Å to cover the surface 19 of the stopper layer 9.

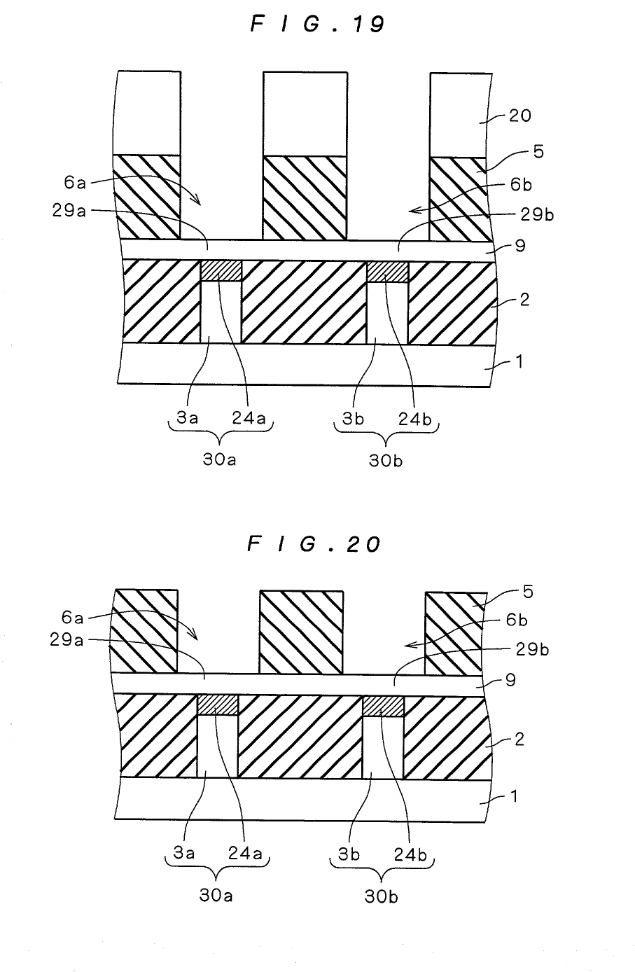

Next, as shown in FIG. 19, holes 6a and 6b are formed in the dummy interlayer film 5 by photolithography; the holes 6a and 6b are positioned above the contact plugs 30a and 30b. More specifically, a resist 20 is formed on the dummy interlayer film 5 and patterned. Subsequently the dummy interlayer film 5 is dry-etched by using the resist 20 as a mask to make the holes 6a and 6b in which the stopper layer 9 is exposed. As shown in FIG. 20, the resist 20 used to form the holes 6a and 6b is then removed.

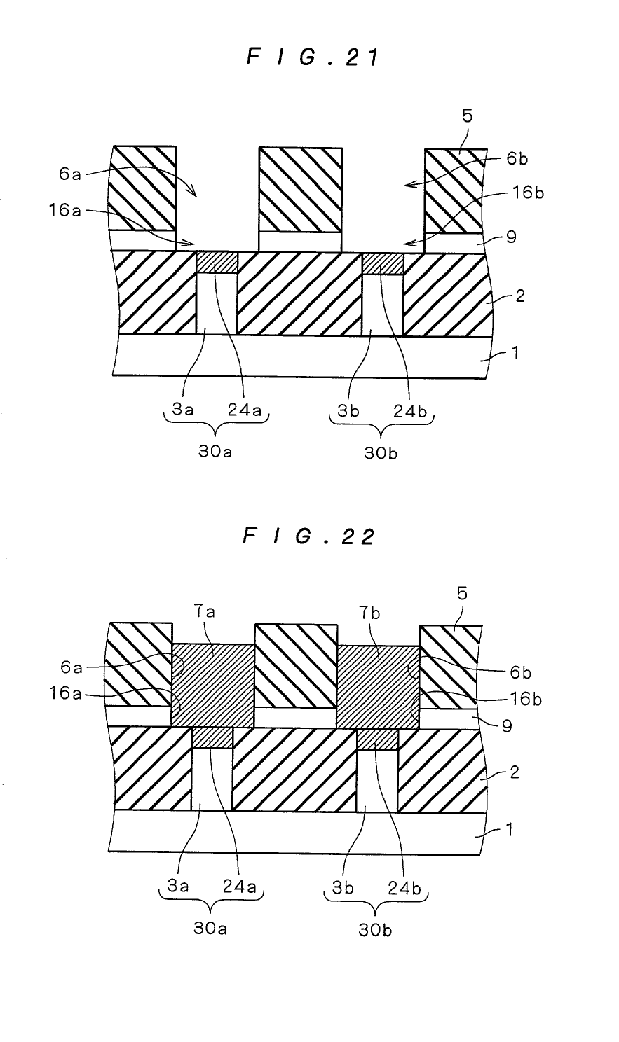

Next, as shown in FIG. 21, the exposed parts 29a and 29b of the stopper layer 9 are selectively removed by wet etching to form holes 16a and 16b in the stopper layer 9; the underlying noble metal layers 24a and 24b are exposed respectively in the holes 16a and 16b. More specifically, when Ti, TiN or TiAlN is used as the material of the stopper layer 9, the wet etching is performed using a hydrogen peroxide solution or a mixture solution of sulfuric acid and hydrogen peroxide solution. When TiSiN is used as the material of the stopper layer 9, the wet etching is performed using a mixture solution of hydrofluoric acid and hydrogen peroxide solution.

Next, as shown in FIG. 22, by taking advantage of the catalytic action of the material of the underlying noble metal layers 24a and 24b, i.e. a platinum-group metal, lower electrodes 7a and 7b are selectively formed in the holes 6a and 6b and the holes 16a and 16b. The lower electrodes 7a and 7b, as well as the underlying noble metal layers 24a and 24b, are formed of a platinum-group metal such as platinum.

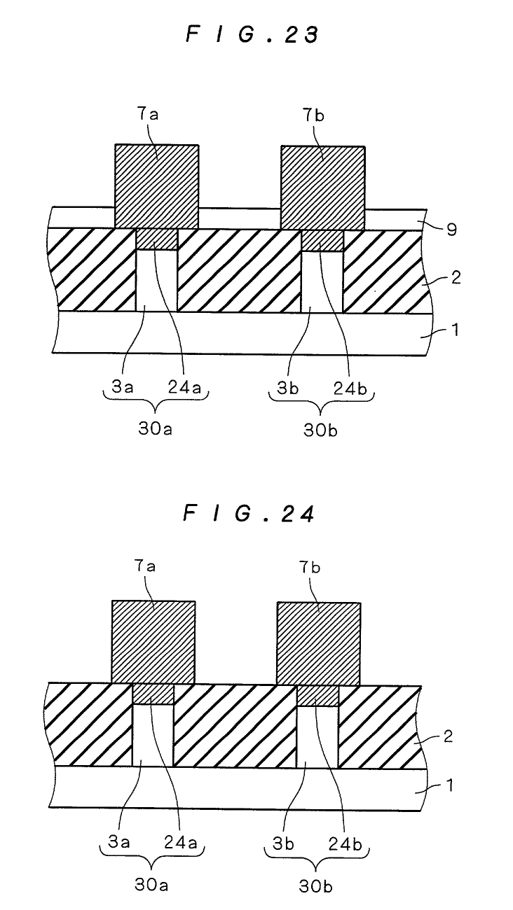

Next, as shown in FIG. 23, the dummy interlayer film 5 is selectively removed by using a dilute HF solution and the stopper layer 9 is selectively removed by wet etching as shown in FIG. 24. More specifically, as in the process shown in FIG. 21, when Ti, TiN or TiAlN is used as the material of the stopper layer 9, the stopper layer 9 is selectively removed by wet etching using a hydrogen peroxide solution or a mixture solution of sulfuric acid and hydrogen peroxide solution, and when TiSiN is used as the material of the stopper layer 9, the stopper layer 9 is selectively removed by wet etching using a mixture solution of hydrofluoric acid and hydrogen peroxide solution.

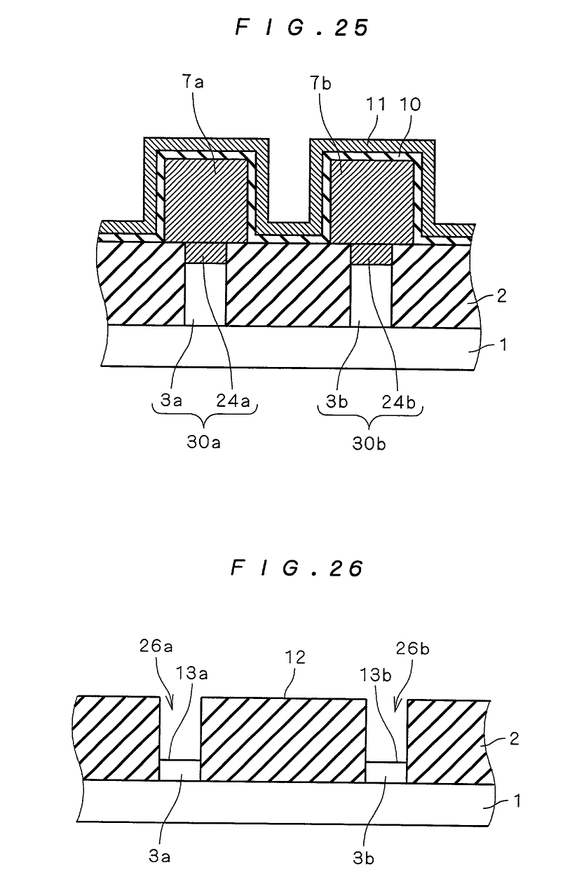

Next, as shown in FIG. 25, the dielectric film 10 is formed to 200 to 300 Å to cover the surface of the lower electrodes 7a and 7b and the interlayer insulating film 2, and the upper electrode 11 is formed to 300 to 500 Å on the dielectric film 10; capacitors incorporated in a DRAM are thus completed.

According to the capacitor manufacturing method of the second preferred embodiment shown in FIGS. 13 to 25, the contact plugs 30a and 30b have the underlying noble metal layers 24a and 24b formed in their respective upper ends in the process shown in FIG. 16. In other words, the underlying noble metal layers 24a and 24b are formed respectively in the contact plugs 30a and 30b. Accordingly, the lower electrodes 7a and 7b are already separated when they are formed in the holes 6a and 6b and the holes 16a and 16b in the process of FIG. 22.

In contrast, in the capacitor manufacturing method of the first preferred embodiment, the underlying noble metal layer 4 is formed to cover the top surfaces 13a and 13b of the contact plugs 3a and 3b and the surface 12 of the interlayer insulating film 2. In such a case, when the lower electrodes 7a and 7b are formed in the holes 6a and 6b and the holes 16a and 16b in the process of FIG. 8, the lower electrodes 7a and 7b are connected to each other through the underlying noble metal layer 4. Accordingly this method requires the process of FIG. 11 after the process of FIG. 8; i.e. it requires the process of selectively removing the underlying noble metal layer 4 to separate the lower electrodes 7a and 7b. In this case, in the process shown in FIG. 11, since the lower electrodes 7a and 7b made of the same kind of material as the underlying noble metal layer 4 are used as etching masks, the upper ends of the lower electrodes 7a and 7b may be removed, in which case the lower electrodes 7a and 7b cannot be formed in desired shape, making it difficult to obtain capacitors with desired capacitance.

However, in the capacitor manufacturing method of the second preferred embodiment, as described above, the lower electrodes 7a and 7b are already separated when they are formed in the holes 6a and 6b and the holes 16a and 1 6b in the process of FIG. 22. This method is thus free from the problem above, without the need to separate the lower electrodes 7a and 7b after they have been formed. The second preferred embodiment thus provides, as well as the effects of the first preferred embodiment, the effect that the capacitors can be easily formed in desired shape.

In the recessing process in the capacitor manufacturing method of the second preferred embodiment, the upper ends of the contact plugs 3a and 3b are etched to recess the top surfaces 13a and 13b of the contact plugs 3a and 3b from the surface 12 of the interlayer insulating film 2. The contact plugs 3a and 3b can be etched deeper, i.e. not only their upper ends but also deeper parts can be etched, to recess the top surfaces 13a and 13b from the surface 12 of the interlayer insulating film 2.

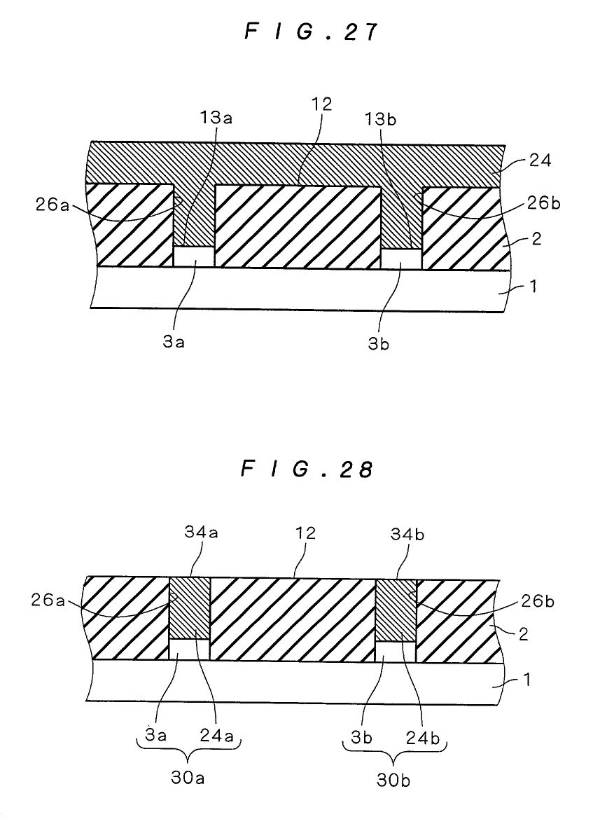

More specifically, as shown in FIG. 26, the contact plugs 3a and 3b are selectively etched from their top surfaces 13a and 13b toward the substrate 1 so that the top surfaces 13a and 13b of the contact plugs 3a and 3b are recessed by 2000 to 3000 Å from the surface 12 of the interlayer insulating film 2, and the holes 26a and 26b are thus formed in the interlayer insulating film 2. Next, as shown in FIG. 27, the conductive material 24 is formed by CVD to 1000 to 1500 Å to cover the top surfaces 13a and 13b of the contact plugs 3a and 3b and the surface 12 of the interlayer insulating film 12, and the conductive material 24 is thus buried in the holes 26a and 26b. Next, as shown in FIG. 28, the conductive material 24 is etched by sputter etching using a mixture gas of Ar and O₂, so that the conductive material 24 remains only in the holes 26a and 26b, so as to form the underlying noble metal layers 24a and 24b in the holes 26a and 26b. At this time, the surfaces 34a and 34b of the underlying noble metal layers 24a and 24b are exposed in the surface 12 of the interlayer insulating film 2. Since the recessing process of FIG. 26 recesses the top surfaces 13a and 13b of the contact plugs 3a and 3b deeper than the recessing process of FIG. 14, CVD, having better coverage than sputtering, is used in the process of FIG. 27 to form the conductive material 24 in the holes 26a and 26b and on the surface 12 of the interlayer insulating film 2.

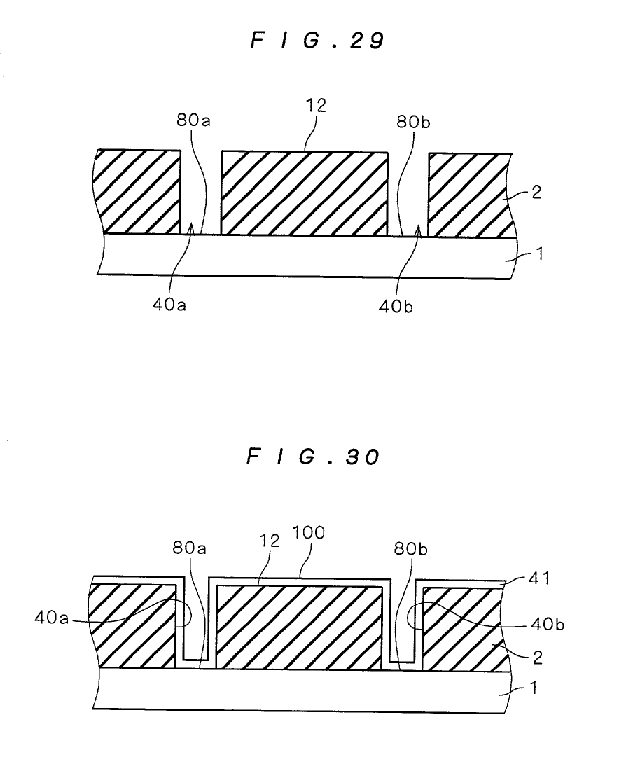

The contact plugs in the second preferred embodiment may be formed with a barrier metal layer and an underlying noble metal layer. More specifically, as shown in FIG. 29, holes 40a and 40b are formed in given positions in the interlayer insulating film 2 on the substrate 1; the substrate 1 is exposed in the holes 40a and 40b. Next, as shown in FIG. 30, a barrier metal material 41 is formed to 200 to 500 Å by CVD to cover the exposed surfaces 80a and 80b of the substrate 1 and the surface 12 of the interlayer insulating film 2. The barrier metal material 41 is TiN, TiSiN or TiAlN, for example.

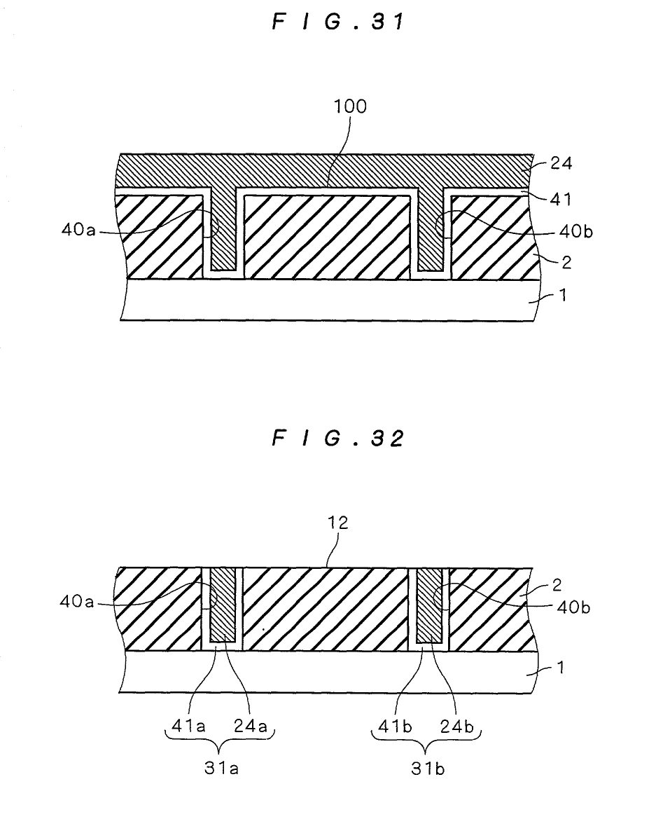

Next, as shown in FIG. 31, the electrically conductive material 24 is formed, e.g. by CVD, to about 1000 Å to cover the surface 100 of the barrier metal material 41 and thus buried in the holes 40a and 40b. Next, as shown in FIG. 32, the conductive material 24 is removed by sputter etching using a mixture gas of Ar and O₂, so that the conductive material 24 remains only in the holes 40a and 40b, so as to form the underlying noble metal layers 24a and 24b in the holes 40a and 40b. Next, the barrier metal material 41 is removed by plasma etching using a gas containing Cl₂, so that the barrier metal material 41 remains only in the holes 40a and 40b, so as to form barrier metal layers 41a and 41b in the holes 40a and 40b. As a result the barrier metal layers 41a and 41b and the underlying noble metal layers 24a and 24b form contact plugs 31a and 31b. The barrier metal layers 41a and 41b and the underlying noble metal layers 24a and 24b are exposed in the surface 12 of the interlayer insulating film 2. The barrier metal layers 41a and 41b prevent reaction between the substrate 1 of silicon and the underlying noble metal layers 24a and 24b of platinum-group metal, thus preventing an increase in contact resistance between the contact plugs 31a and 31b and the substrate 1.

The structures of the contact plugs shown in FIGS. 16, 28 and 32 are common in that they have the underlying noble metal layers 24a and 24b at least in their upper ends. That is to say, as for the structure of the contact plugs, the lower electrodes 7a and 7b can be selectively formed in the holes 6a and 6b and the holes 16a and 16b and the effects shown above can be obtained as long as the contact plugs have the underlying noble metal layers 24a and 24b at least in the upper ends.

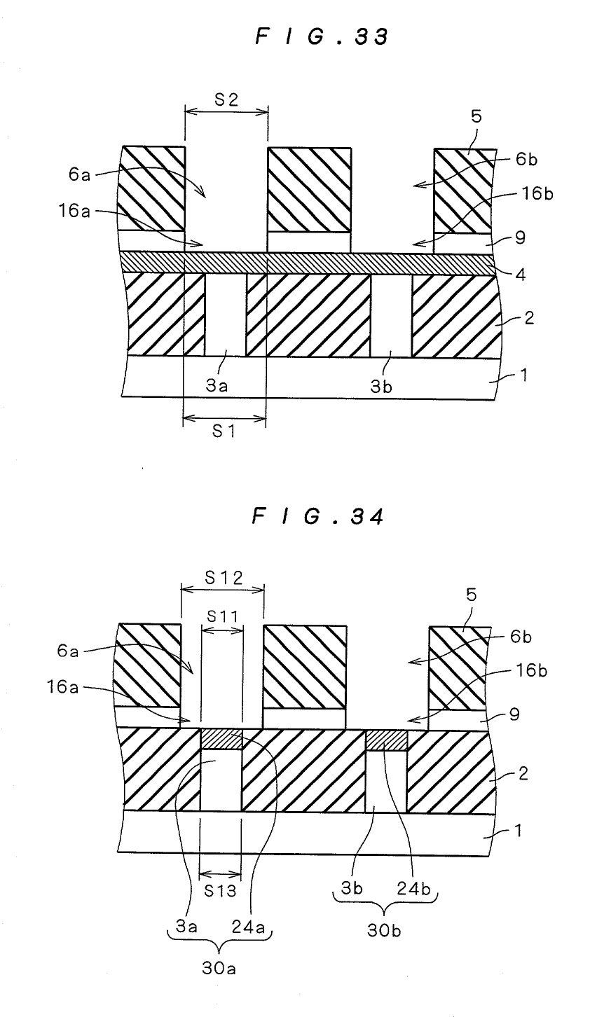

When the first preferred embodiment and the second preferred embodiment are compared as to the process of selectively forming the lower electrodes 7a and 7b in the holes 6a and 6b and the holes 16a and 16b, the lower electrodes 7a and 7b may be formed in a shorter time in the first preferred embodiment. This is now more specifically described referring to FIGS. 33 to 35.

In the first preferred embodiment, the underlying noble metal layer 4 is formed to cover the surface 12 of the interlayer insulating film 2 and the top surfaces 13a and 13b of the contact plugs 3a and 3b. Accordingly, as shown in FIG. 33, the exposed surface area S1 (simply referred to as “exposed area” hereinafter) of the underlying noble metal layer 4, which is exposed by formation of the holes 16a and 16b, is equal to the opening area S2 of the holes 16a and 16b.

In contrast, in the second preferred embodiment, the contact plugs 30a and 30b respectively have the underlying noble metal layers 24a and 24b formed in their upper ends. Accordingly, the exposed area S11 of the underlying noble metal layers 24a and 24b, which is exposed by formation of the holes 16a and 16b, is equivalent to or smaller than the opening area S12 of the holes 16a and 16b. More specifically, as shown in FIG. 34, when the opening area S12 of the holes 16a and 16b is larger than the diameter S13 of each contact plug, the exposed area S11 of the underlying noble metal layers 24a and 24b is equivalent to the diameter S13 of the contact plugs and smaller than the opening area S12 of the holes 16a and 16b.

When, as shown in FIG. 35, the opening area S12 of the holes 16a and 16b is smaller than the diameter S13 of the contact plugs, the exposed area S11 of the underlying noble metal layers 24a and 24b is equivalent to the opening area S12 of the holes 16a and 16b. That is, when holes each having an opening area larger than the diameter of each contact plug is formed, the exposed area S11 of each of the underlying noble metal layers 24a and 24b of the second preferred embodiment is smaller than the exposed area S1 of the underlying noble metal layer 4 of the first preferred embodiment.

Since the lower electrodes 7a and 7b are formed by utilizing the catalytic action of the material of the underlying noble metal layers, the lower electrodes 7a and 7b can be formed in a shorter time as the underlying noble metal layer has a larger exposed area. Therefore, when holes having opening areas larger than the contact plug diameter are formed, the lower electrodes 7a and 7b can be formed in a shorter time in the first preferred embodiment than in the second preferred embodiment.

Third Preferred Embodiment

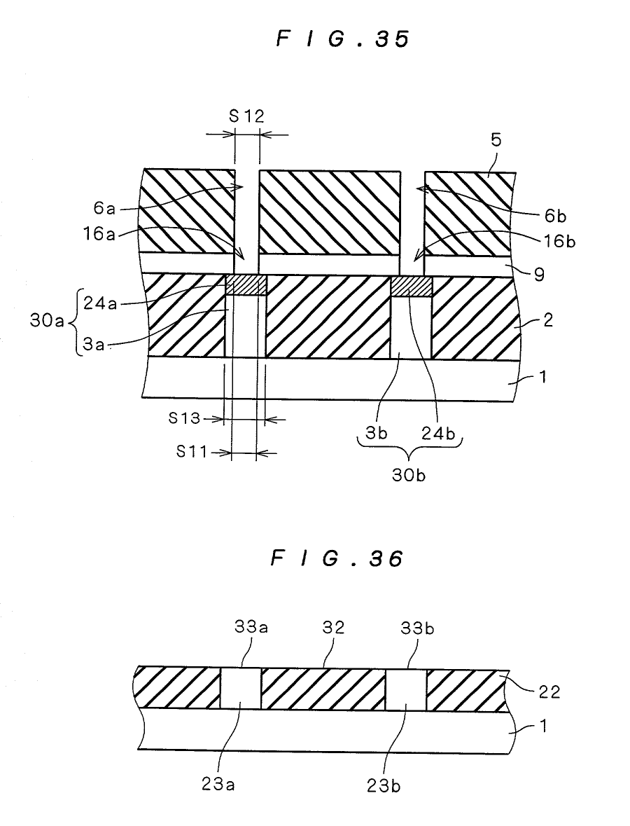

FIGS. 36 to 49 are sectional views showing a capacitor manufacturing process according to a third preferred embodiment of the present invention. In the second preferred embodiment shown above, the underlying noble metal layers 24a and 24b and the contact plugs 3a and 3b are formed in a single layer of interlayer insulating film 2. However, in the third preferred embodiment, two layers of interlayer insulating films 22 and 42 are formed and underlying noble metal layers 44a and 44b and contact plugs 23a and 23b are formed in different interlayer insulating films.

First, as shown in FIG. 36, an interlayer insulating film 22, e.g. a silicon oxide film, is formed on the substrate 1 and contact plugs 23a and 23b in electrical contact with the substrate 1 are formed at an given interval in the interlayer insulating film 22. At this time, the top surface of the structure obtained in the process shown in FIG. 36 is planarized by using CMP and the top surfaces 33a and 33b of the contact plugs 23a and 23b are exposed in the surface 32 of the interlayer insulating film 22. The top surfaces 33a and 33b of the contact plugs 23a and 23b are located in approximately the same plane with the surface 32 of the interlayer insulating film 22. In other words, the process shown in FIG. 36 is a process of forming, in the interlayer insulating film 22, the contact plugs 23a and 23b having their respective top surfaces 33a and 33b exposed in the surface 32 of the interlayer insulating film 22.

The interlayer insulating film 22 is a silicon oxide film formed with TEOS by CVD and the contact plugs 23a and 23b are formed of polysilicon, tungsten (W), or titanium nitride (TiN) formed by CVD, for example. The contact plugs 23a and 23b each have a diameter of 1000 to 1500 Å.

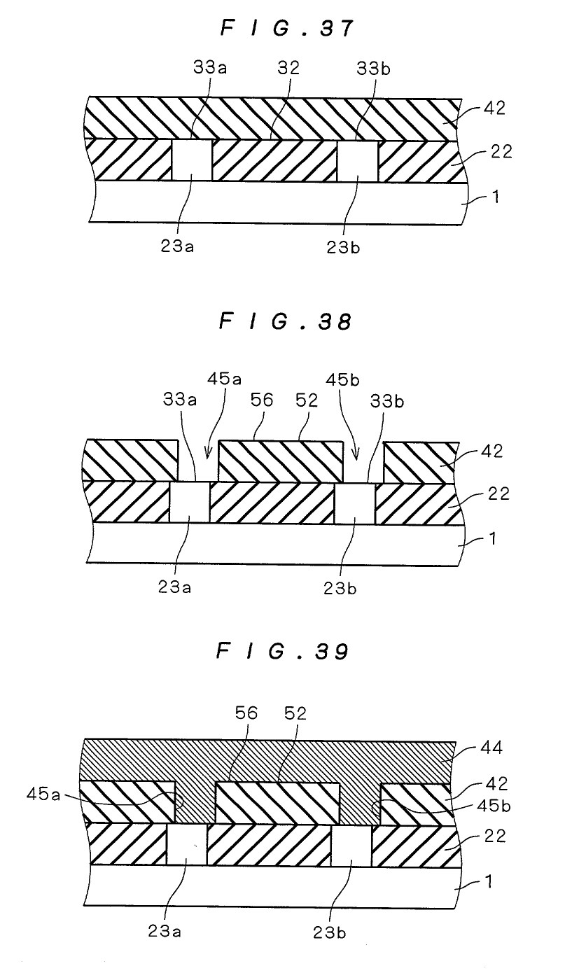

Next, as shown in FIG. 37, an interlayer insulating film 42, e.g. a silicon oxide film, is formed to cover the surface 32 of the interlayer insulating film 22 and the top surfaces 33a and 33b of the contact plugs 23a and 23b. Next, as shown in FIG. 38, holes 45a and 45b reaching the top surfaces 33a and 33b of the contact plugs 23a and 23b are formed in the interlayer insulating film 42. The holes 45a and 45b each have a diameter of 1000 to 1500 Å.

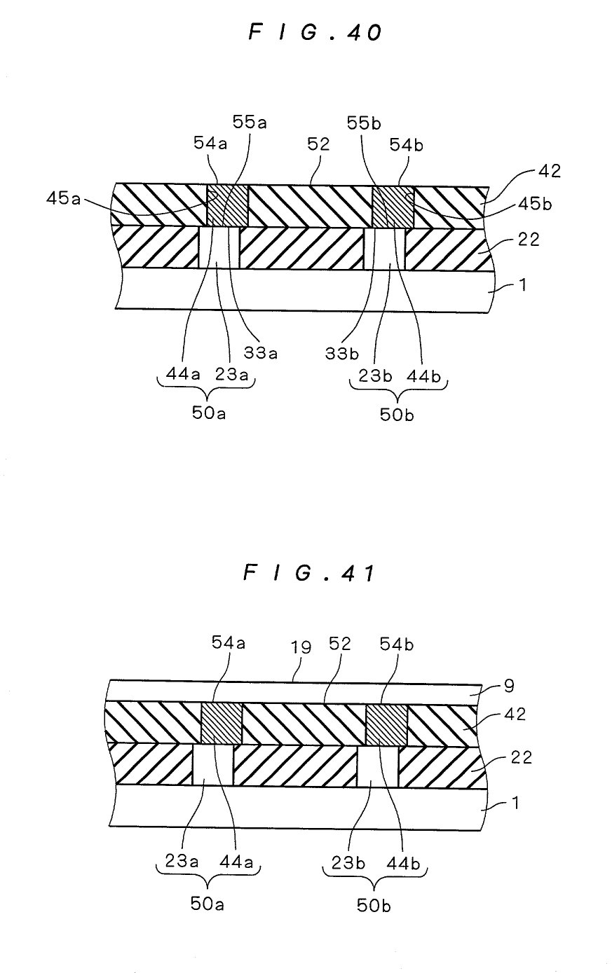

Next, as shown in FIG. 39, an electrically conductive material 44 is formed to 1000 to 1500 Å by CVD on the exposed surface 56 of the structure obtained in the process of FIG. 38 and the conductive material 44 is thus buried in the holes 45a and 45b. Next, as shown in FIG. 40, the conductive material 44 is removed by sputter etching using a mixture gas of Ar and O₂ so that the conductive material 44 remains only in the holes 45a and 45b, whereby the underlying noble metal layers 44a and 44b are formed in the holes 45a and 45b. At this time, the top surfaces 54a and 54b of the underlying noble metal layers 44a and 44b are exposed in the surface 52 of the interlayer insulating film 42, and the bottom surfaces 55a and 55b of the underlying noble metal layers 44a and 44b are in contact with the top surfaces 33a and 33b of the contact plugs 23a and 23b. In other words, the processes shown in FIGS. 39 and 40 can be regarded together as a process of forming in the interlayer insulating film 42 the underlying noble metal layers 44a and 44b having their respective bottom surfaces 55a and 55b in contact with the top surfaces 33a and 33b of the contact plugs 23a and 23b and their respective top surfaces 54a and 54b exposed in the surface 52 of the interlayer insulating film 42. The conductive material 44, i.e. the underlying noble metal layers 44a and 44b, are made of a platinum-group metal.

The underlying noble metal layers 44a and 44b are buried in the interlayer insulating film 42 and used together with the contact plugs 23a and 23b to make connection between the substrate 1 and the lower electrodes 7a and 7b described later. Therefore the underlying noble metal layers 44a and 44b may be regarded as contact plugs and called “contact plugs 44a and 44b.” Also, the underlying noble metal layers 44a and 44b and the contact plugs 23a and 23b may be called “contact plugs 50a and 50b” together.

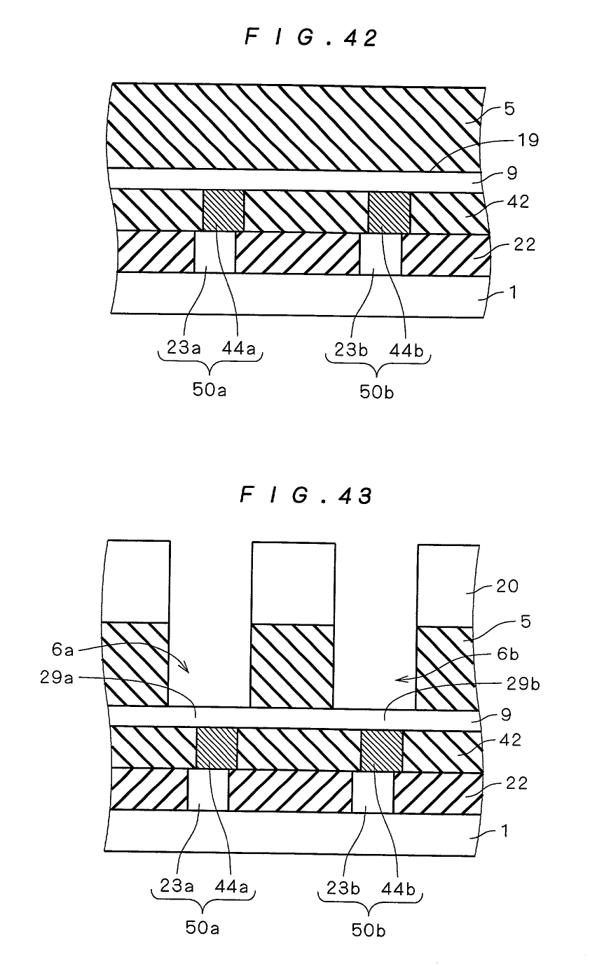

Next, as shown in FIG. 41, the stopper layer 9 is formed to 500 to 1000 Å to cover the surface 52 of the interlayer insulating film 42 and the top surfaces 54a and 54b of the underlying noble metal layers 44a and 44b. The stopper layer 9 is made of Ti, TiN, TiSiN, or TiAlN, for example. Next, as shown in FIG. 42, the dummy interlayer film 5, e.g. a silicon oxide film, is formed to 4000 to 8000 Å to cover the surface 19 of the stopper layer 9.

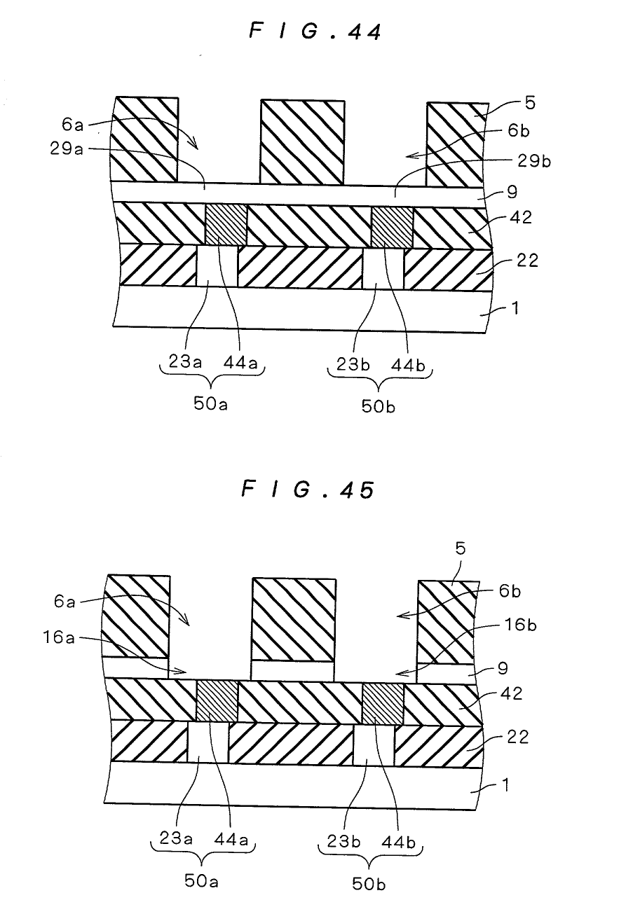

Next, as shown in FIG. 43, holes 6a and 6b, located above the contact plugs 50a and 50b, are formed in the dummy interlayer film 5 by photolithography. More specifically, a resist 20 is formed on the dummy interlayer film 5 and patterned. Subsequently the dummy interlayer film 5 is dry-etched by using the resist 20 as a mask to form holes 6a and 6b in which the stopper layer 9 is exposed. Next, as shown in FIG. 44, the resist 20 used to form the holes 6a and 6b is removed.

Next, as shown in FIG. 45, the exposed parts 29a and 29b of the stopper layer 9 are selectively removed by wet etching to form holes 16a and 16b in the stopper layer 9; the underlying noble metal layers 44a and 44b are exposed in the holes 16a and 16b. More specifically, when Ti, TiN or TiAlN is used as the material of the stopper layer 9, the wet etching is performed by using a hydrogen peroxide solution or a mixture solution of sulfuric acid and hydrogen peroxide solution. When TiSiN is used as the material of the stopper layer 9, the wet etching is performed by using a mixture solution of hydrofluoric acid and hydrogen peroxide solution.

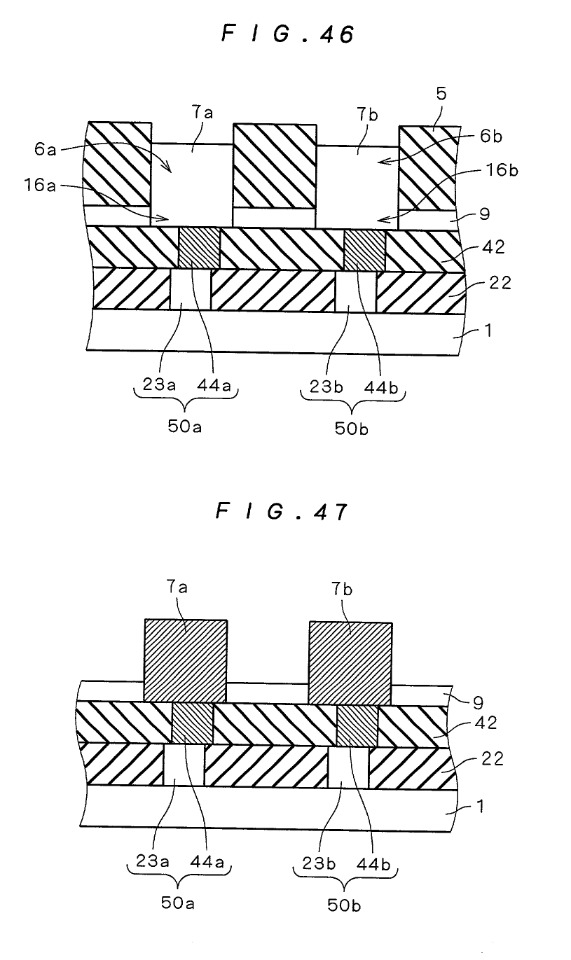

Next, as shown in FIG. 46, by utilizing the catalytic action of the material of the underlying noble metal layers 44a and 44b, i.e. platinum-group metal, the lower electrodes 7a and 7b are selectively formed in the holes 6a and 6b and the holes 16a and 16b. Like the underlying noble metal layers 44a and 44b, the lower electrodes 7a and 7b are made of a platinum-group metal, e.g. platinum.

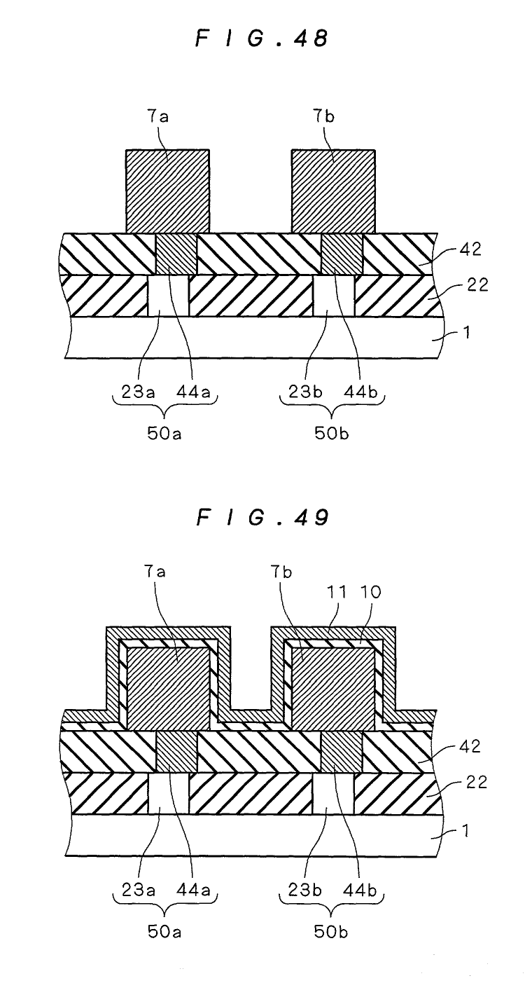

Next, as shown in FIG. 47, the dummy interlayer film 5 is selectively removed with a dilute HF solution and the stopper layer 9 is selectively removed as shown in FIG. 48 by wet etching. More specifically, as in the process of FIG. 45, when Ti, TiN or TiAlN is used as the material of the stopper layer 9, the stopper layer 9 is selectively removed by wet etching using a hydrogen peroxide solution or a mixture solution of sulfuric acid and hydrogen peroxide solution, and when TiSiN is used as the material of the stopper layer 9, the stopper layer 9 is selectively removed by wet etching using a mixture solution of hydrofluoric acid and hydrogen peroxide solution.

Next, as shown in FIG. 49, the dielectric film 10 is formed to 200 to 300 Å to cover the surface of the lower electrodes 7a and 7b and the interlayer insulating film 2 and the upper electrode 11 is formed to 300 to 500 Å on the dielectric film 10; capacitors incorporated in a DRAM are thus completed.

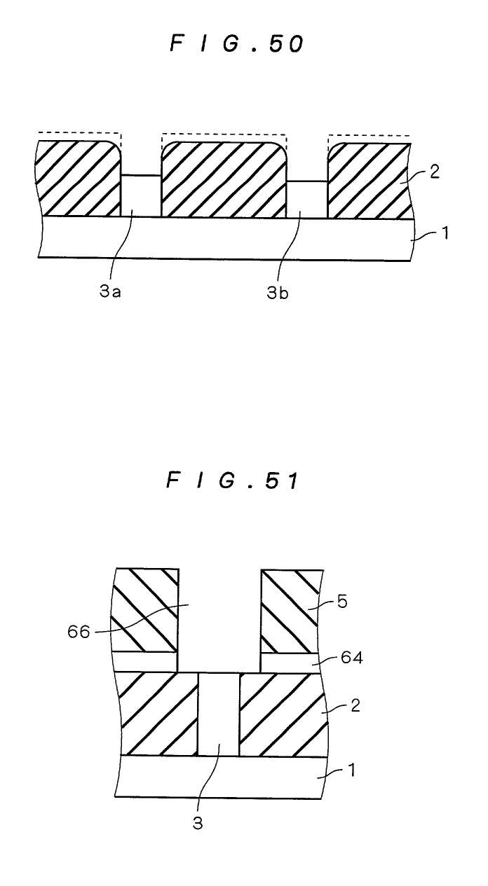

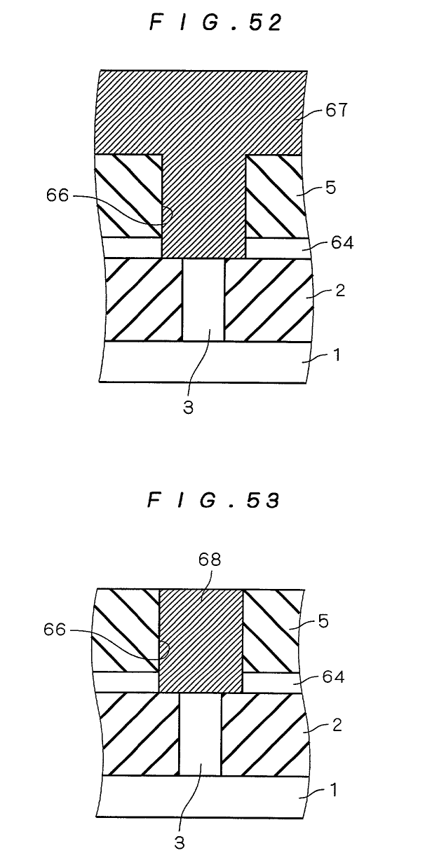

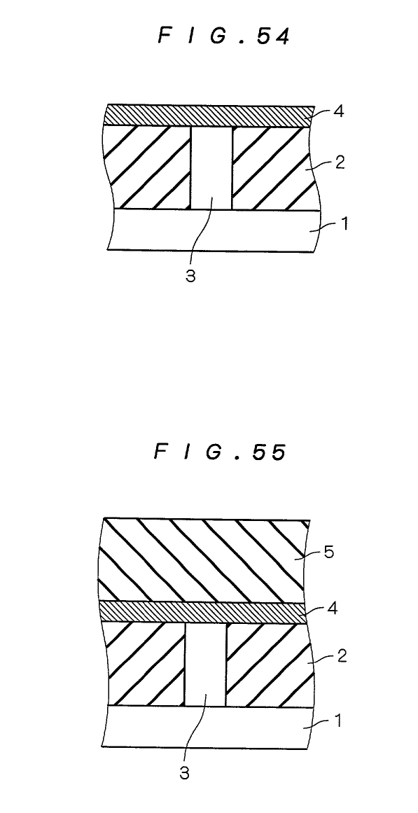

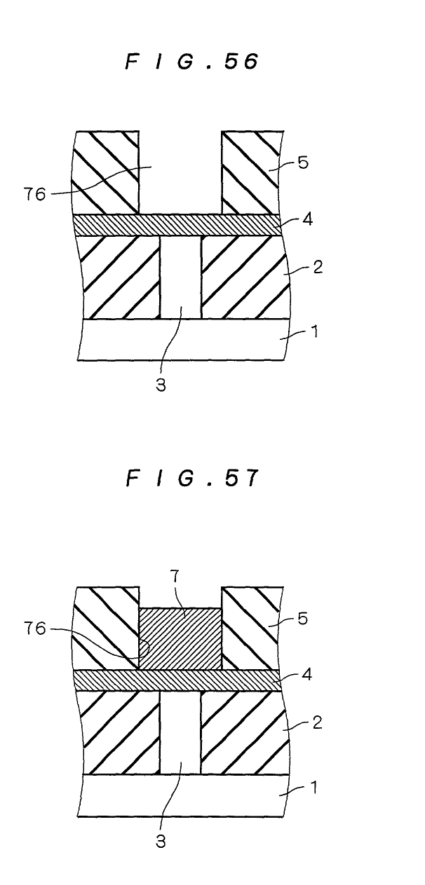

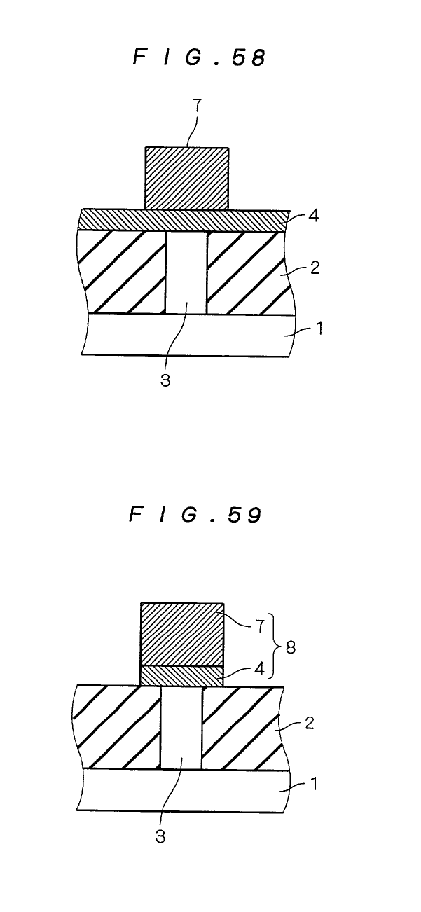

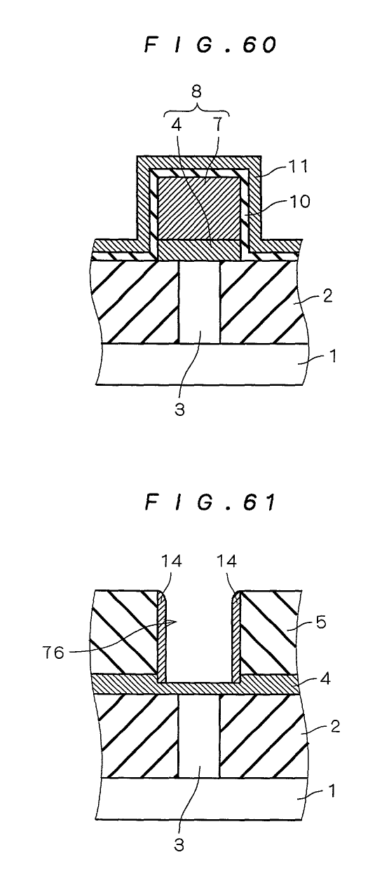

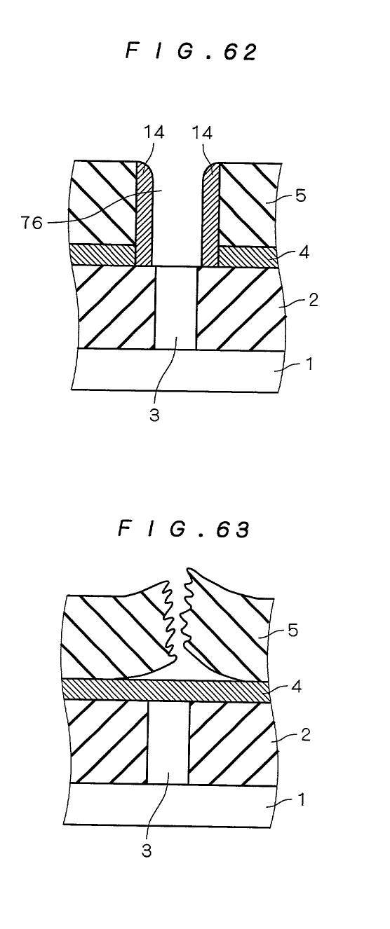

According to the capacitor manufacturing method of the third preferred embodiment shown in FIGS. 36 to 49, the contact plugs 23a and 23b and the underlying noble metal layers 44a and 44b are formed in different interlayer insulating films. This eliminates the need for the recessing process described in the second preferred embodiment. The recessing process of the second preferred embodiment encounters the following problem. That is to say, depending on the materials of the contact plugs 3a and 3b and the interlayer insulating film 2, or depending on the etching conditions, the selectivity cannot be sufficiently obtained and the interlayer insulating film 2 may be removed when the contact plugs 3a and 3b are selectively removed, making it difficult to form the contact plugs 30a and 30b in desired shape. FIG. 50 shows the top of the interlayer insulating film 2 removed during the recessing process in the second preferred embodiment.

Since the capacitor manufacturing method of the third preferred embodiment does not require the recessing process for formation of the contact plugs 50a and 50b, the above-mentioned problem can be solved and the contact plugs 50a and 50b can be easily formed in desired shape.

While the invention has been described in detail, the foregoing description is in all aspects illustrative and not restrictive. It is understood that numerous other modifications and variations can be devised without departing from the scope of the invention.

What is claimed is:

1. A capacitor manufacturing method, comprising the steps of:
(a) forming an underlying noble metal layer;
(b) forming a stopper layer to cover a surface of said underlying noble metal layer;
(c) forming a dummy interlayer film to cover a surface of said stopper layer;
(d) forming a first hole in said dummy interlayer film, said stopper layer being exposed in said first hole;
(e) after said step (d), selectively removing the exposed part of said stopper layer to form a second hole in said stopper layer, said underlying noble metal layer being exposed in said second hole; and
(f) selectively forming a lower electrode in said first and second holes by utilizing catalytic action of the material of said underlying noble metal layer.

2. The capacitor manufacturing method according to claim 1, wherein said stopper layer is made of a material having better adhesion to said dummy interlayer film than said underlying noble metal layer.

3. The capacitor manufacturing method according to claim 1, further comprising a step (g) of, before said step (a), forming, in an interlayer insulating film, a contact plug having its top surface exposed in a surface of said interlayer insulating film, wherein in said step (a), said underlying noble metal layer is formed to cover said surface of said interlayer insulating film and said top surface of said contact plug.

4. The capacitor manufacturing method according to claim 2, further comprising a step (g) of, before said step (a), forming, in an interlayer insulating film, a contact plug having its top surface exposed in a surface of said interlayer insulating film,
wherein in said step (a), said underlying noble metal layer is formed to cover said surface of said interlayer insulating film and said top surface of said contact plug.

5. The capacitor manufacturing method according to claim 1,
wherein said step (a) is achieved by forming, in an interlayer insulating film, a contact plug having said underlying noble metal layer at least in its upper end, said surface of said underlying noble metal layer being exposed in a surface of said interlayer insulating film, and
in said step (b), said stopper layer is formed to also cover said surface of said interlayer insulating film.

6. The capacitor manufacturing method according to claim 2,
wherein said step (a) is achieved by forming, in an interlayer insulating film, a contact plug having said underlying noble metal layer at least in its upper end, said surface of said underlying noble metal layer being exposed in a surface of said interlayer insulating film, and
in said step (b), said stopper layer is formed to also cover said surface of said interlayer insulating film.

7. The capacitor manufacturing method according to claim 5,
wherein said interlayer insulating film comprises a first interlayer insulating film and a second interlayer insulating film, and
said contact plug comprises a first contact plug and a second contact plug which is said underlying noble metal layer, and wherein said step (a) comprises the steps of,
(g) forming, in said first interlayer insulating film, said first contact plug having its top surface exposed in a surface of said first interlayer insulating film,
(h) forming said second interlayer insulating film to cover said surface of said first interlayer insulating film and said top surface of said first contact plug, and
(i) forming, in said second interlayer insulating film, said second contact plug having its bottom surface in contact with said top surface of said first contact plug and its top surface exposed in a surface of said second interlayer insulating film, and
in said step (b), said stopper layer is formed to cover said top surface of said second contact plug and said surface of said second interlayer insulating film.

8. The capacitor manufacturing method according to claim 6,
wherein said interlayer insulating film comprises a first interlayer insulating film and a second interlayer insulating film, and
said contact plug comprises a first contact plug and a second contact plug which is said underlying noble metal layer,
and wherein said step (a) comprises the steps of,
(g) forming, in said first interlayer insulating film, said first contact plug having its top surface exposed in a surface of said first interlayer insulating film,
(h) forming said second interlayer insulating film to cover said surface of said first interlayer insulating film and said top surface of said first contact plug, and
(i) forming, in said second interlayer insulating film, said second contact plug having its bottom surface in contact with said top surface of said first contact plug and its top surface exposed in a surface of said second interlayer insulating film, and
in said step (b), said stopper layer is formed to cover said top surface of said second contact plug and said surface of said second interlayer insulating film.

9. The capacitor manufacturing method according to claim 1, wherein said underlying noble metal layer is made of a platinum-group metal.

10. The capacitor manufacturing method according to claim 9, wherein said platinum-group metal is platinum.

11. The capacitor manufacturing method according to claim 1, further comprising, between said step (b) and said step (c), a step (g) of oxidizing said stopper layer.

12. The capacitor manufacturing method according to claim 5,
wherein said step (a) comprises the steps of,
(g) forming said interlayer insulating film on a substrate,
(h) after said step (g), forming a third hole in said interlayer insulating film, said substrate being exposed in said third hole,
(i) after said step (h), forming a barrier metal layer on said exposed substrate, and
(j) forming said underlying noble metal layer to cover a surface of said barrier metal layer.
